(19) United States
(12) Patent Application Publication
(10) Pub. No.: US 2015/0076592 A1
(43) Pub. Date: Mar. 19, 2015

(54) SEMICONDUCTOR DEVICE AND METHOD OF MANUFACTURING THE SEMICONDUCTOR DEVICE

(71) Applicant: KABUSHIKI KAISHA TOSHIBA, Tokyo (JP)

(72) Inventor: Hidetoshi ASAHARA, Hyogo (JP)

(73) Assignee: KABUSHIKI KAISHA TOSHIBA, Tokyo (JP)

(21) Appl. No.: 14/191,247

(22) Filed: Feb. 26, 2014

(30) Foreign Application Priority Data
Sep. 13, 2013 (JP) 2013-191131

(51) Int. Cl. H01L 29/40; H01L 29/423; H01L 21/765; H01L 21/28

(52) U.S. Cl. CPC H01L 29/402; H01L 21/28008; H01L 29/4236; H01L 21/765
USPC 257/330; 438/430

(57) ABSTRACT

A method of manufacturing a semiconductor device includes: forming a trench on a semiconductor layer of a first conductive type; forming a first insulation film which covers an inner surface of the trench; forming a first conductive material on the first insulation film; etching the first conductive material and then the first insulation film such that the semiconductor layer is exposed on an inner surface of an upper portion of the trench and an upper end portion of the first conductive material is positioned above an upper end portion of the first insulation film; re-etching the first conductive material; forming a second insulation film which covers the semiconductor layer exposed on the inner surface of the upper portion of the trench and the first conductive material; and forming a second conductive material on the first insulation film and the second insulation film.

### CROSS-REFERENCE TO RELATED APPLICATION

This application is based upon and claims the benefit of priority from Japanese Patent Application No. 2013-191131, filed Sep. 13, 2013; the entire contents of which are incorporated herein by reference.

### FIELD

Embodiments described herein relate to a method of manufacturing a semiconductor device.

### BACKGROUND

To realize miniaturization and attain high performance of a power transistor, a vertical transistor is configured such that the gate electrode is embedded in a trench. To employ a vertical transistor having the gate electrode embedded in the trench to attain high performance of the power transistor, the capacitance (feedback capacitance) between a gate electrode and a drain electrode thereof is decreased by locating the field plate electrode in the trench below the gate electrode. However, when the field plate electrode is disposed in the trench, there is a possibility that a capacitance between the field plate electrode and the gate electrode will degrade the performance of the transistor.

### DESCRIPTION OF THE DRAWINGS

FIG. 1 is a schematic cross-sectional view of a semiconductor device according to a first embodiment.

FIG. 2 is a schematic cross-sectional view showing a portion of the device during manufacturing of the semiconductor device according to the first embodiment.

FIG. 3 is a schematic cross-sectional view showing a portion of the device during manufacturing of the semiconductor device according to the first embodiment.

FIG. 4 is a schematic cross-sectional view showing a portion of the device during the manufacturing of the semiconductor device according to the first embodiment.

FIG. 5 is a schematic cross-sectional view showing a portion of the device during the manufacturing of the semiconductor device according to the first embodiment.

FIG. 6 is a schematic cross-sectional view showing a portion of the device during the manufacturing of the semiconductor device according to the first embodiment.

FIG. 7 is a schematic cross-sectional view showing a portion of the device during the manufacturing of the semiconductor device according to the first embodiment.

FIG. 8 is a schematic cross-sectional view showing a portion of the device during the manufacturing of the semiconductor device according to the first embodiment.

FIG. 9 is a schematic cross-sectional view showing a portion of the device during the manufacturing of the semiconductor device according to the first embodiment.

FIG. 10 is a schematic cross-sectional view showing a portion of the device during the manufacturing of the semiconductor device according to the first embodiment.

FIG. 11 is a schematic cross-sectional view showing a portion of the device during the manufacturing of the semiconductor device according to the first embodiment.

FIG. 12 is a schematic cross-sectional view of a semiconductor device according to a comparison embodiment.

FIG. 13 is a schematic cross-sectional view showing a portion of the device during manufacturing of the semiconductor device according to the comparison embodiment.

FIG. 14 is a schematic cross-sectional view showing a portion of the device during the manufacturing of the semiconductor device according to the comparison embodiment.

FIG. 15 is a schematic cross-sectional view of a semiconductor device according to a second embodiment.

FIG. 16 is a schematic cross-sectional view showing a portion of the device during manufacturing of the semiconductor device according to the second embodiment.

FIG. 17 is a schematic cross-sectional view showing a portion of the device during the manufacturing of the semiconductor device according to the second embodiment.

### DETAILED DESCRIPTION

According to an embodiment, there is provided a method of manufacturing a semiconductor device where a capacitance between a field plate electrode and a gate electrode can be decreased.

In general, according to one embodiment, a method of manufacturing a semiconductor device includes: forming a trench on a semiconductor layer of a first conductive type; forming a first insulation film which covers an inner surface of the trench; forming a first conductive material on the first insulation film such that the first conductive material is embedded in the trench; etching the first conductive material such that an upper end portion of the first conductive material is positioned in the trench; etching the first insulation film such that the semiconductor layer is exposed on an inner surface of an upper portion of the trench and the upper end portion of the first conductive material is positioned above an upper end portion of the first insulation film; re-etching the first conductive material such that the upper end portion of the first insulation film is positioned above the upper end portion of the first conductive material after etching the first insulation film; forming a second insulation film which covers the semiconductor layer exposed on the inner surface of the upper portion of the trench and the first conductive material; and forming a second conductive material on the second insulation film such that the second conductive material is embedded in the trench.

Hereinafter, embodiments are explained in conjunction with drawings. In the explanation made hereinafter, same symbols are given to identical parts or the like, and when parts or the like are once described, repeated descriptions of these parts or the like is omitted when appropriate.

In this disclosure, “anisotropic etching” means etching where an etching rate in the direction that the etching rate is greatest is five times or more as large as an etching rate in the direction that the etching rate is the smallest. “Isotropic etching” means etching where an etching rate in the direction that the etching rate is the greatest is two times or less as large as an etching rate in the direction that the etching rate is the smallest.

### First Embodiment

A method of manufacturing a semiconductor device according to this embodiment includes: forming a trench on a semiconductor layer of a first conductive type; forming a first insulation film which covers an inner surface of the trench; forming a first conductive material on the first insulation film such that the first conductive material is embedded in the trench; etching the first conductive material such that an upper end portion of the first conductive material is positioned in the trench; etching the first insulation film such that the semiconductor layer is exposed on an inner surface of an upper portion of the trench and the upper end portion of the first conductive material is positioned above an upper end portion of the first insulation film; re-etching the first conductive material such that the upper end portion of the first insulation film is positioned above the upper end portion of the first conductive material after etching the first insulation film; forming a second insulation film which covers the semiconductor layer exposed on the inner surface of the upper portion of the trench and the first conductive material; and forming a second conductive material on the second insulation film such that the second conductive material is embedded in the trench.

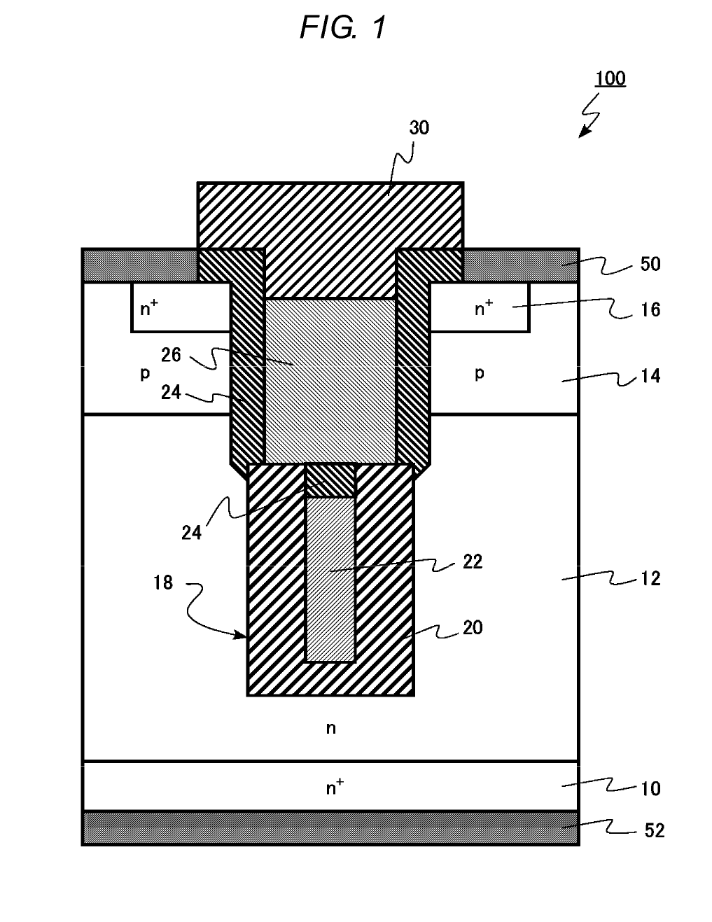

FIG. 1 is a schematic cross-sectional view of a semiconductor device manufactured by the method of manufacturing a semiconductor device according to this embodiment. The semiconductor device 100 of this embodiment is a vertical MOSFET (Metal Oxide Semiconductor Field Effect Transistor) which includes a gate electrode in a trench. Hereinafter, the explanation is made by taking a MOSFET where a first conductive type is n type and a second conductive type is p type, that is, a MOSFET of an n-channel type as an example. The semiconductor device (MOSFET) 100 of this embodiment includes an n-type semiconductor layer (semiconductor layer) 12 on an n⁺type substrate 10. The n⁺type substrate 10 and the n-type semiconductor layer 12 are made of single crystalline silicon containing an n-type dopant, for example.

Concentration of n-type dopant in the n-type semiconductor layer 12 is lower than the concentration of n-type dopant in the n⁺type substrate 10. The n-type dopant is phosphorus (P) or arsenic (As), for example. The n⁺type substrate 10 and the n-type semiconductor layer 12 function as a drain region of the MOSFET 100.

A p-type semiconductor region (first semiconductor region) 14 is disposed on the n-type semiconductor layer 12. The p-type semiconductor region 14 is made of single crystalline silicon containing a p-type dopant. The p-type dopant is boron (B), for example. The p-type semiconductor region (first semiconductor region) 14 functions as a base region (channel region) of the MOSFET 100.

An n-type semiconductor region (second semiconductor region) 16 is disposed in portions of the p-type semiconductor region (first semiconductor region) 14 located over the n-type semiconductor layer 12. The n-type semiconductor region 16 is made of single crystalline silicon containing n-type dopant. The n-type dopant is phosphorus (P) or arsenic (As), for example. The n-type semiconductor region 16 functions as a source region of the MOSFET 100.

A trench 18 which extends inwardly of the semiconductor layers 12, 14 and 16, and it terminates within n-type semiconductor layer 12, and has an opening portion and a base which ends above, i.e, is spaced from the n⁺type substrate 10 with a portion of the n-type semiconductor extending between the bottom portion and the n⁺substrate 10. A field plate electrode (first conductive material) 22 is disposed in the trench 18 with a field plate insulation film (first insulation film) 20 interposed between the field plate electrode 22 and the n-type semiconductor layer 12.

The field plate insulation film 20 is a silicon oxide film, for example. The field plate electrode 22 is made of polycrystalline silicon doped with a dopant, for example.

A gate electrode (second conductive material) 26 is formed in the trench 18 such that agate insulation film (second insulation film) 24 is interposed between the gate electrode 26 and the p-type semiconductor region 14.

The gate insulation film. 24 is a silicon oxide film, for example. The gate electrode 26 is made of polycrystalline silicon doped with a dopant, for example.

An interlayer insulation film. 30 is formed over the gate electrode 26 embedded in the trench 18. The interlayer insulation film 30 is a silicon oxide film, for example.

The gate electrode 26 and the field plate electrode 22 are insulated from each other by the gate insulation film 24.

A source electrode (first electrode) 50 is formed on the n-type semiconductor region (second semiconductor region) 16 and the p-type semiconductor region (first semiconductor region) 14. The source electrode 50 is made of metal, for example.

A drain electrode (second electrode) 52 is formed on a surface of the n⁺type substrate 10 on a side opposite to the n-type semiconductor layer 12. The drain electrode 52 is made of metal, for example.

The field plate electrode 22 has the same potential as the source electrode 50, for example. By setting the potential of the field plate electrode 22 equal to the potential of the source electrode 50, the parasitic capacitance (feedback capacitance) between the gate electrode 26 and the n-type semiconductor layer 12 which constitutes the drain region is decreased. Accordingly, the MOSFET 100 can realize a fast switching characteristic and the low power consumption.

Further, the potential of the field plate electrode 22 may be also set equal to the potential of the gate electrode 26. By setting the potential of the field plate electrode 22 equal to the potential of the gate electrode 26, the ON resistance of the device can be decreased, for example. This is because electrons accumulate in the n-type semiconductor layer 12 which faces the field plate electrode 22 in an opposed manner when the transistor is in an ON state.

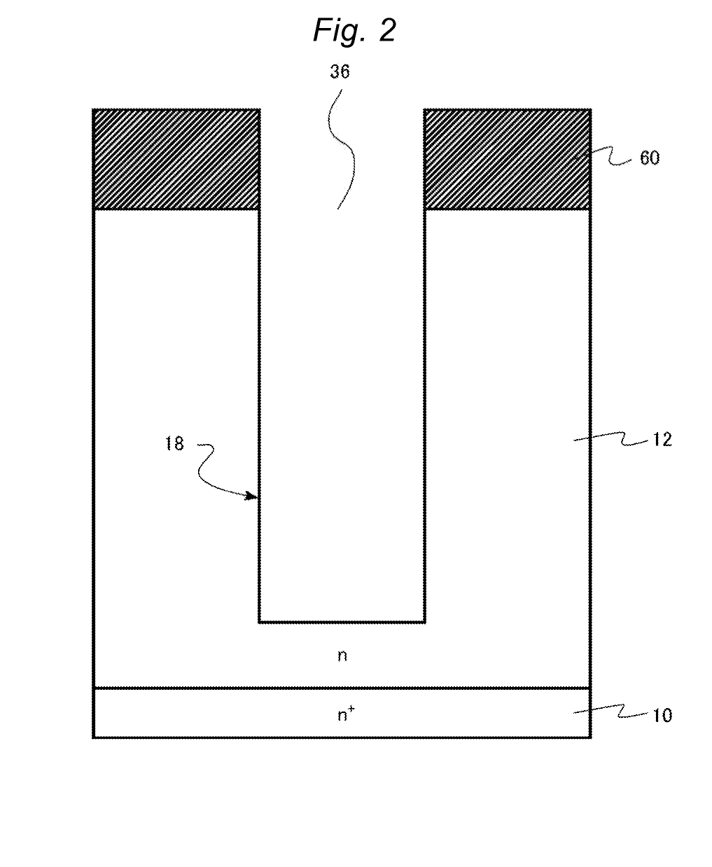

Next, a method of manufacturing a semiconductor device according to this embodiment is explained. FIG. 2 to FIG. 11 are schematic cross-sectional views showing the states of the semiconductor device in the method of manufacturing the semiconductor device of this embodiment.

Firstly, an n-type semiconductor layer (semiconductor layer) 12 made of single crystalline silicon which contains n-type dopant is formed on the single crystal n⁺type doped silicon substrate 10 by an epitaxial growth method, for example.

Next, a mask material 60 made of a silicon oxide film is formed on a surface of the n-type semiconductor layer 12, for example. The mask material 60 is formed by film deposition using a Chemical Vapor Deposition (CVD), lithography (spin on) or Reactive Ion Etching (RIE) process. The mask material 60 is patterned, such as using traditional photolithographic techniques.

Next, the n-type semiconductor layer 12 is etched using the mask material 60 as a mask to form the trench 18 having the opening portion 36 on a surface of the n-type semiconductor layer 12 (see FIG. 2). The mask material 60 is formed of a silicon oxide film, for example. Etching is performed by RIE (reactive ion etching), for example. A depth of the trench 18 is set to 1.0 μm to 2.0 μm, and a width of the opening portion 36 is set to 0.3 μm to 0.5 μm, for example.

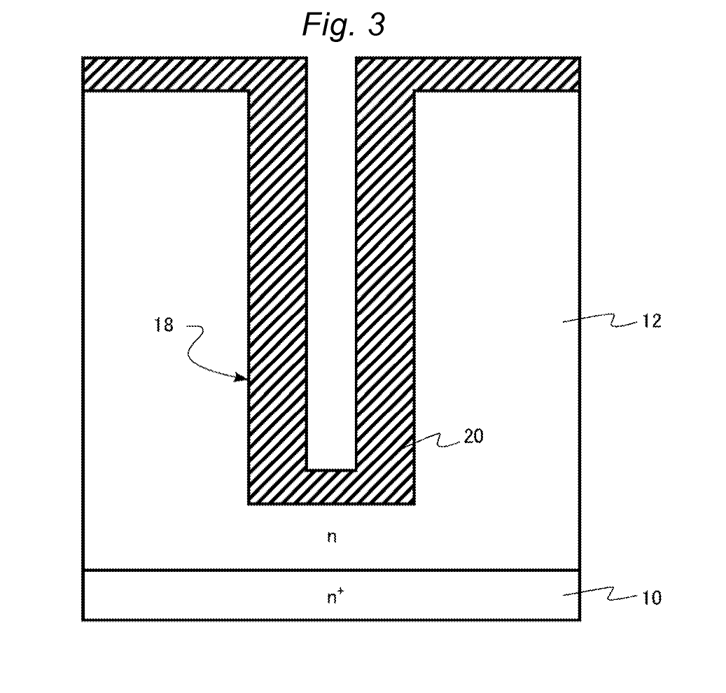

Next, the mask material 60 is removed by wet etching, for example. Thereafter, the field plate insulation film (first insulation film) 20 which covers the inner surface of the trench 18 is formed (see FIG. 3). The field plate insulation film 20 is a thermal oxide film of silicon formed by thermally oxidizing the n-type semiconductor layer 12, for example.

The field plate insulation film 20 may have the laminated (multi-layer) structure comprising a thermal oxide film, for example, and a deposition film formed thereover by a CVD method, for example. For example, the field plate insulation film 20 has the laminated structure comprised of a thermal oxide film of silicon and a deposition film of silicon.

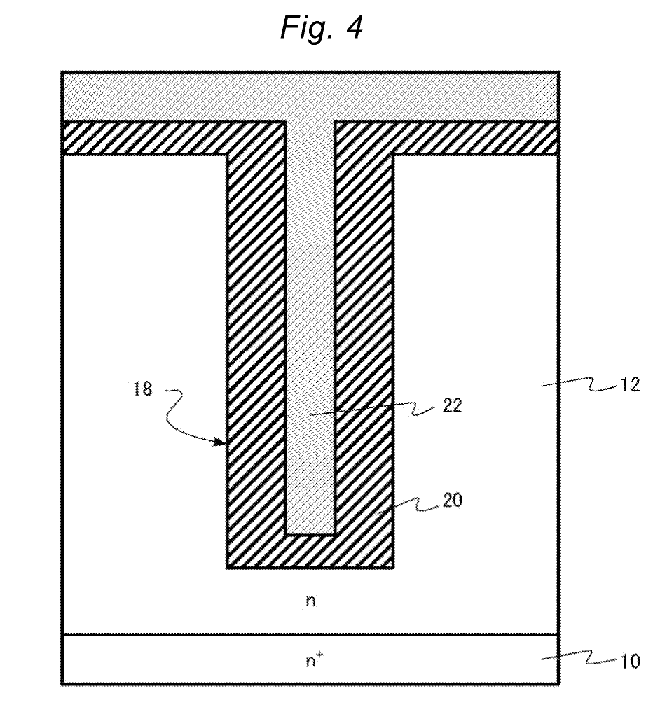

Next, the first conductive material 22 is formed such that the first conductive material 22 is embedded in the trench (see FIG. 4). The first conductive material 22 is polycrystalline silicon doped with a dopant, for example. A portion of the first conductive material 22 eventually forms the field plate electrode 22. The first conductive material 22 may also be a metal semiconductor compound or metal.

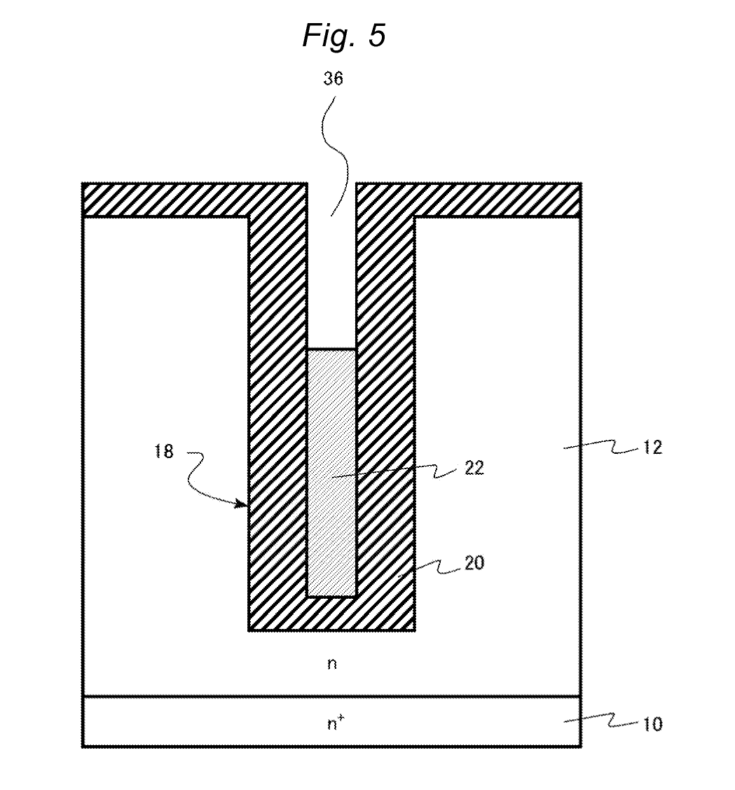

Next, portions of the first conductive material 22 is etched such that the upper end portion (terminus) of the first conductive material 22 is positioned in the trench 18 (see FIG. 5). In such etching, the first conductive material 22 is etched such that an end portion of the first conductive material 22 on an opening portion 36 side, that is, the upper end portion of the first conductive material 22 is positioned within the trench 18. That is, the portion of the first conductive material 22 outside the trench 18, and the portion at the upper end of the trench 18, is removed by etching.

The first conductive material 22 may be etched by either isotropic etching such as Chemical Dry Etching (CDE) or anisotropic etching such as RIE.

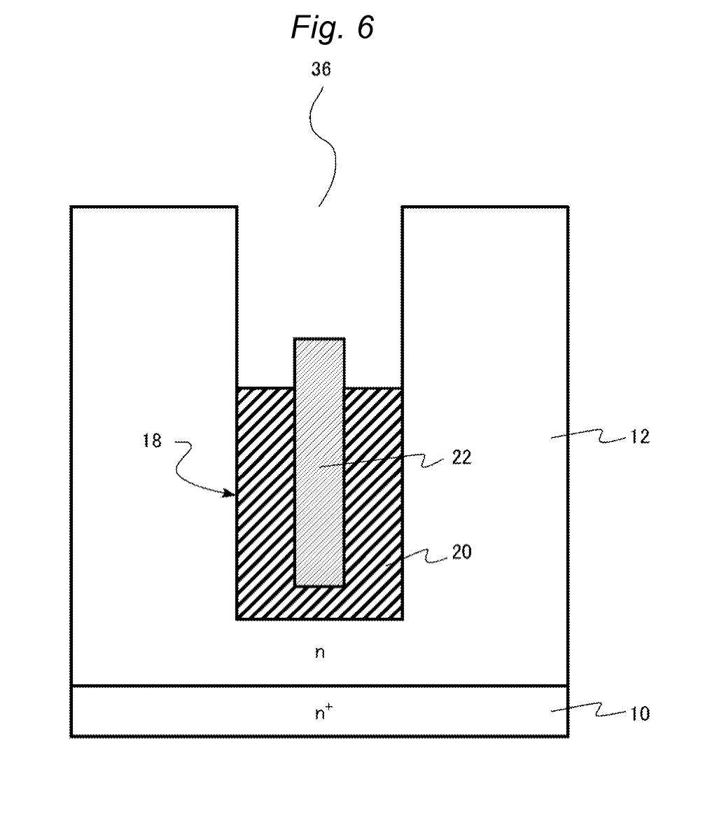

Next, the field plate insulation film (first insulation film) 20 is etched using the first conductive material 22 as a mask such that the n-type semiconductor layer 12 is exposed along the inner surface of the upper portion of the trench 18 (see FIG. 6). In such etching, the field plate insulation film (first insulation film) 20 is etched such that the upper end portion of the first conductive material 22 is positioned above, i.e., extends outwardly from, an upper end portion of the field plate insulation film 20 (first insulation film).

By etching the field plate insulation film (first insulation film) 20 such that the upper end portion of the first conductive material 22 is positioned above the upper end portion of the field plate insulation film (first insulation film) 20 on an opening portion 36 side of the opening 18, it is possible to expose the n-type semiconductor layer 12 on the inner surface of the trench 18 on an opening portion 36 side with a sufficient process margin. The field plate insulation film 20 is etched by wet etching, for example. Wet etching is isotropic etching.

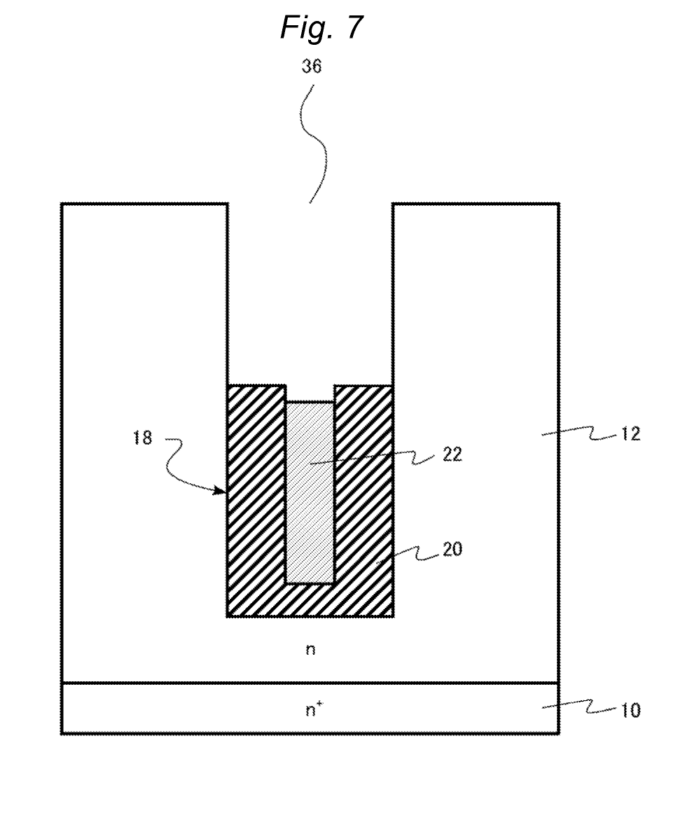

Next, the first conductive material 22 is etched again (see FIG. 7). In such etching, the first conductive material 22 is etched such that the upper end portion of the field plate insulation film (first insulation film) 20 is positioned above the upper end portion of the first conductive material 22, i.e., the upper end portion of the first conductive material 22 is etched such that it is recessed in the field plate insulation film 20.

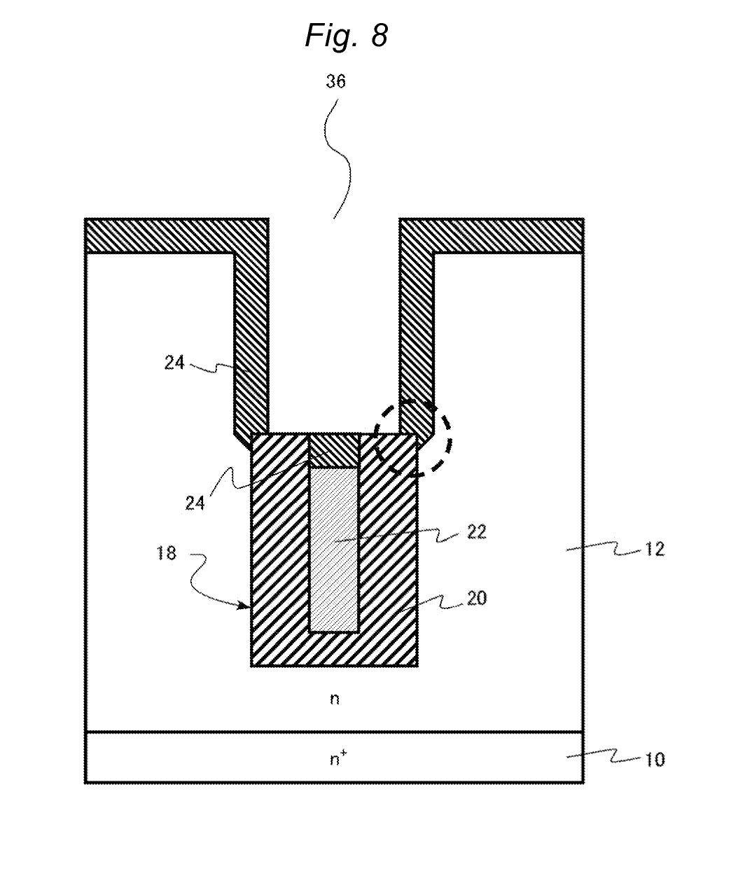

Re-etching of the first conductive material 22 is performed by anisotropic etching. Anisotropic etching is performed by, for example, RIE. By etching the first conductive material 22 using anisotropic etching, it is possible to suppress excessive sideward etching of the n-type semiconductor layer 12 exposed along an upper portion of the trench 18. However, as shown in FIG. 8, the upper portion of the trench 18 becomes opened, to have a large cross section, than the portion within which the plate insulating film 20 is formed.

Next, the gate insulation film (second insulation film) 24 is formed to cover the first conductive material 22 and the exposed portions of the n-type semiconductor layer (semiconductor layer) 12 on the inner surface of the upper portion of the trench 18 and the field (top surface of the layer 12) (see FIG. 8). The gate insulation film 24 which covers the n-type semiconductor layer 12 is a thermal oxide film of silicon formed by thermally oxidizing the n-type semiconductor layer 12, for example. The gate insulation film 24 which covers the first conductive material 22 is a thermal oxide film of polycrystalline silicon formed by thermally oxidizing the first conductive material 22.

The gate insulation film (second insulation film) 24 may have a laminated structure constituted of a thermal oxide film, for example, and a deposition film formed thereover by a CVD method, for example. For example, the gate insulation film (second insulation film) 24 has the laminated structure constituted of a thermal oxide film of silicon and a deposition film of silicon.

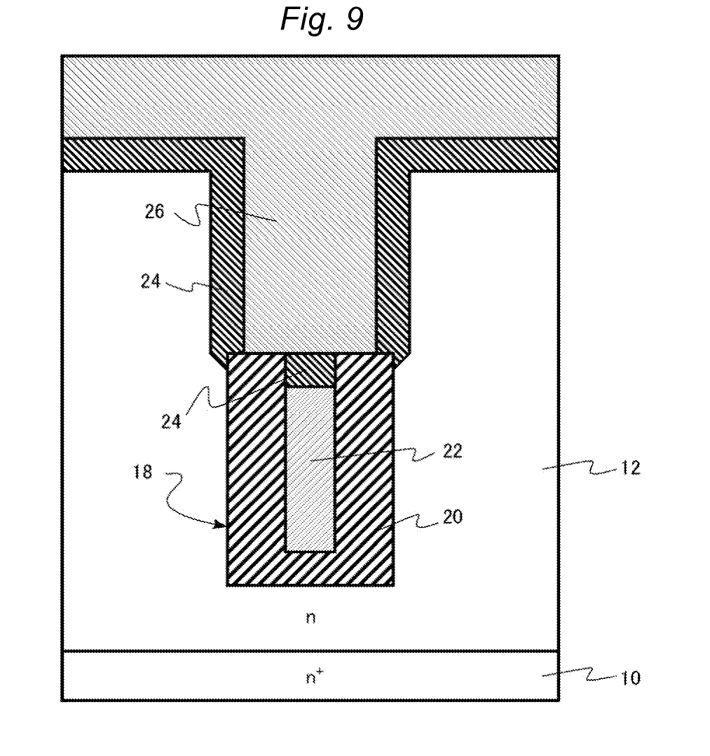

Next, the second conductive material 26 is formed on the gate insulation film (second insulation film) 24 such that the second conductive material 26 is embedded in the trench 18 and extends over the field (see FIG. 9). The second conductive material 26 is polycrystalline silicon doped with dopant, for example. The second conductive material 26 eventually becomes the gate electrode 26. The second conductive material 26 may also be a metal semiconductor compound or metal.

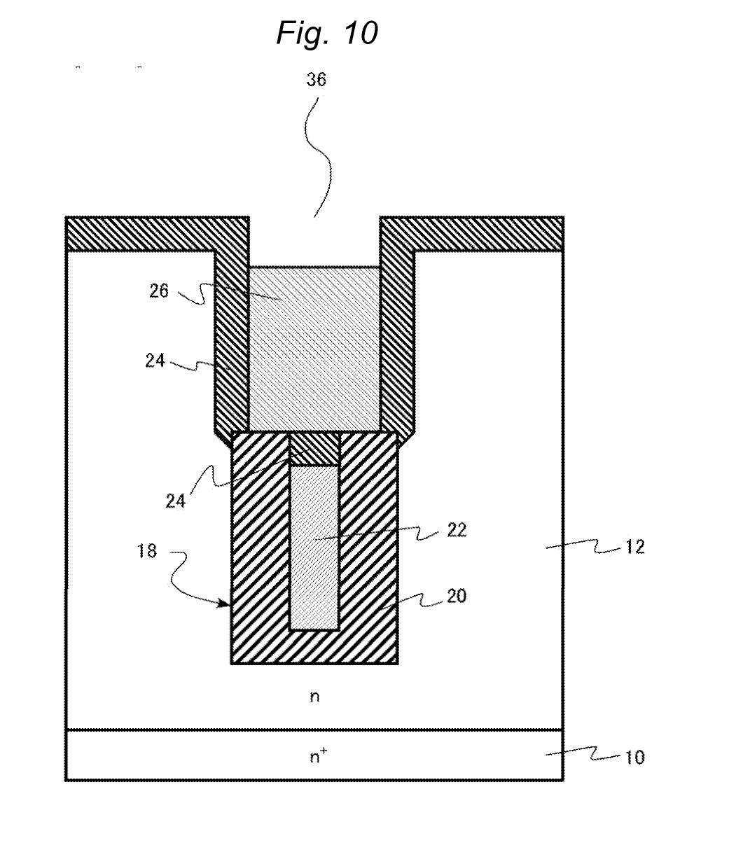

Next, the second conductive material 26 is etched such that an upper end portion of the second conductive material 26 is positioned in the trench 18 (see FIG. 10). In such etching, the second conductive material 26 is etched such that an upper end portion of the second conductive material 26 on an opening portion 36 side of the opening 18, that is, the upper end portion of the second conductive material 26 terminates within the trench 18. That is, the portion of the second conductive material 26 outside the trench 18, and at the opening thereof, is removed by etching.

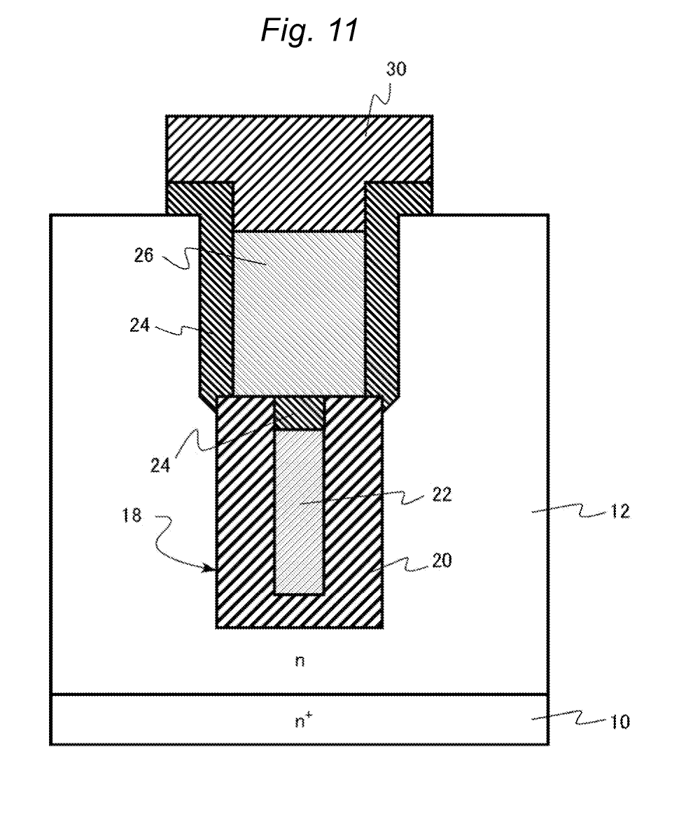

Next, the interlayer insulation film 30 which covers the upper portion of the second conductive material 26 is formed. The interlayer insulation film 30 is a silicon oxide film formed by deposition using a CVD method, for example. Then, the interlayer insulation film 30 and the gate insulation film 26 are patterned using lithography and etching such that the surface of the n-type semiconductor layer 12 is exposed (see FIG. 11). Etching is performed by RIE, for example.

Next, a p-type dopant, for example, B (boron) is implanted into the n-type semiconductor layer 12 by ion implantation thus forming the p-type semiconductor region (first semiconductor region) 14 in the n-type semiconductor layer 12. Next, an n-type dopant, for example, P (phosphorus) or arsenic (As) is injected into the p-type semiconductor region (first semiconductor region) 14 by ion implantation thus forming the n-type semiconductor region (second semiconductor region) 16 in the p-type semiconductor region (first semiconductor region) 14.

Thereafter, using a known manufacturing method, the first electrode 50 and the second electrode 52 are formed so that the MOSFET 100 shown in FIG. 1 is manufactured.

Hereinafter, the manner of operation and advantageous effects of the method of manufacturing a semiconductor device of this embodiment is explained.

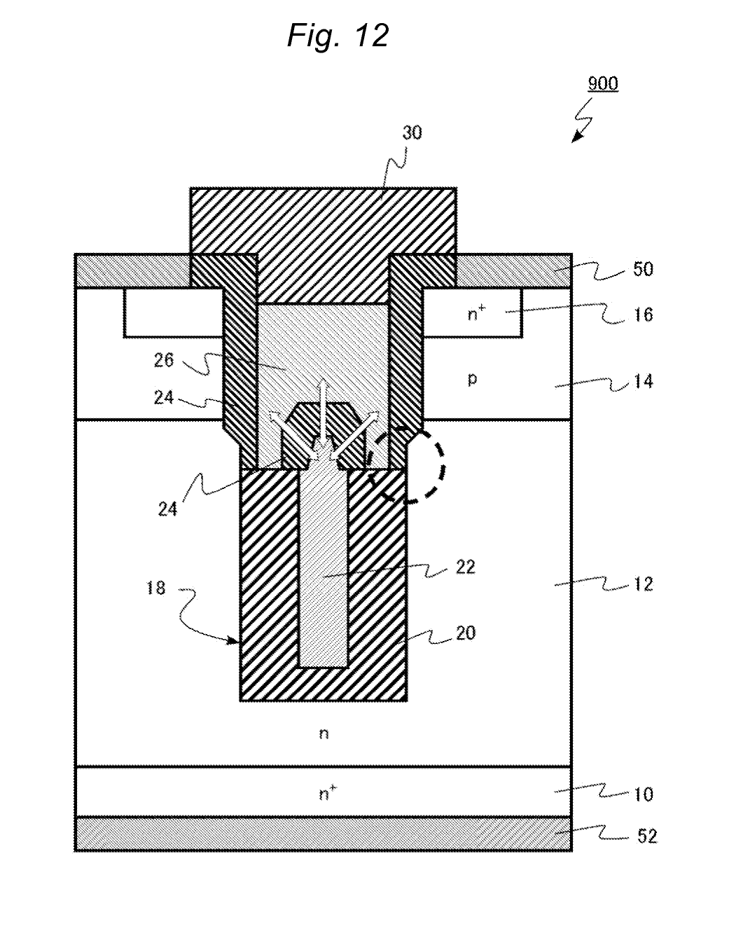

FIG. 12 is a schematic cross-sectional view of a semiconductor device which is manufactured by a method of manufacturing a semiconductor device according to a comparison embodiment. The semiconductor device 900 according to the comparison embodiment is also a vertical MOSFET where a gate electrode is arranged in a trench. The semiconductor device 900 of the comparison embodiment is substantially the same as the MOSFET 100 of the first embodiment except for that a shape of a field plate electrode 22 and a shape of a gate electrode 26 of the comparison embodiment are different from the shape of the field plate electrode 22 and the shape of the gate electrode 26 of the semiconductor device of the first embodiment. Accordingly, the description of the portions of the semiconductor device 900 which are the same as the portions of the MOSFET 100 is omitted.

In the MOSFET 900 of the comparison embodiment, an upper end of the field plate electrode 22 projects outwardly into the gate electrode 26 side of the device.

Due to such constitution, the surface area where the gate electrode 26 and the field plate electrode 22 contact each other is increased in comparison to that in the first embodiment. Accordingly, as schematically shown by white arrows in FIG. 12, capacitance between the gate electrode 26 and the field plate electrode 22 is increased. This gives rise to drawbacks in that a switching characteristic (switching speed) of the MOSFET 900 is deteriorated and the power consumption is increased.

As shown in FIG. 12, a film thickness of the gate insulation film 24 is small in a region at a lower end of the gate electrode 26 as indicated by a dotted line circle. Since the film thickness of the gate insulation film 24 is small in this region, a high electric field is applied locally to the gate insulation film 24. Accordingly, a dielectric breakdown of the gate insulation film 24 is liable to occur and hence, the reliability of the MOSFET 900 is reduced.

The increase of the area where the gate electrode 26 and the field plate electrode 22 face each other in an opposed manner and the small film thickness of the gate insulation film 24 in the above-mentioned region are caused by a method of manufacturing a semiconductor device of the comparison embodiment.

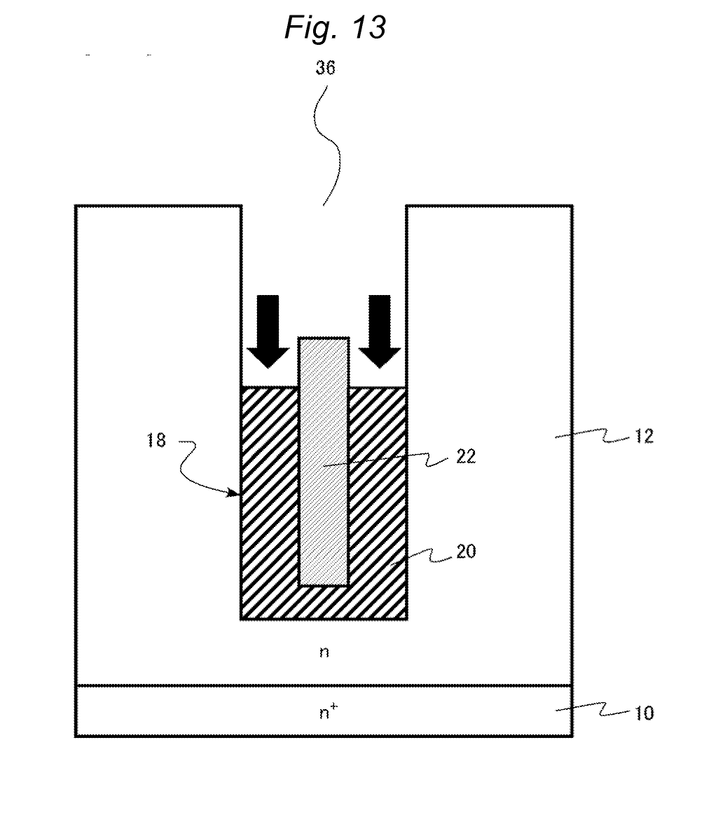

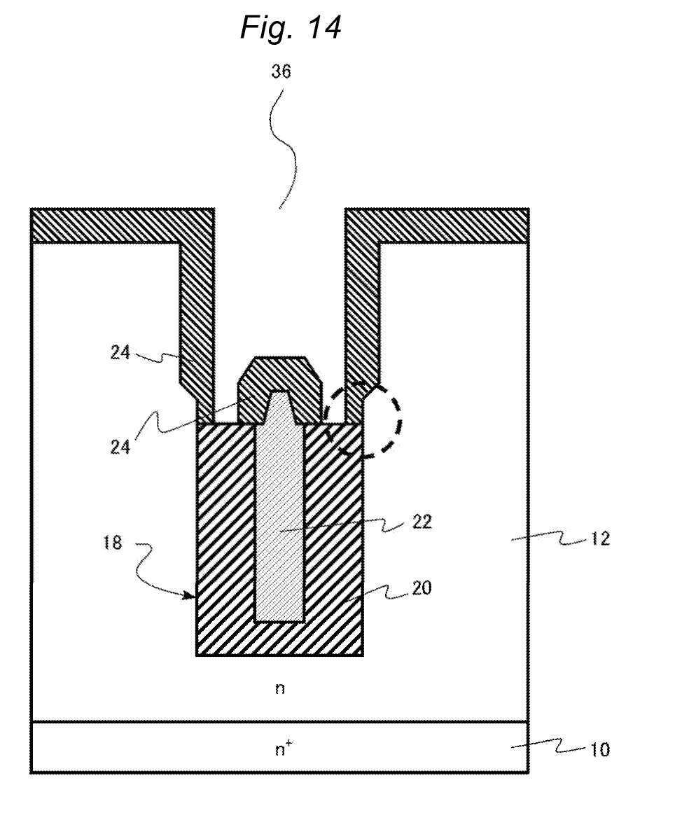

FIG. 13 and FIG. 14 are schematic cross-sectional views showing the method of manufacturing a semiconductor device of the comparison embodiment. In the method of manufacturing a semiconductor device 900 of the comparison embodiment, steps up to a step where the field plate insulation film (first insulation film) 20 is etched as shown in FIG. 13 are substantially equal to the corresponding steps of the method of the first embodiment.

In the comparison embodiment, as shown in FIG. 14, after the field plate insulation film 20 is etched, unlike this embodiment, an n-type semiconductor layer 12 which is exposed on an inner surface of an upper portion of a trench 18 and the gate insulation film 24 which covers a first conductive material 22 are formed without etching the first conductive material 22.

As shown in FIG. 13, immediately before the formation of the gate insulation film. 24, an upper end of the field plate electrode 22 projects toward an opening portion 36 side of the trench 18 from the field insulation film 20. As a result, the area where the gate electrode 26 and the field plate electrode 22 face each other in an opposed manner is increased.

The gate insulation film 24 is formed by thermal oxidation, for example. Immediately before the formation of the gate insulation film 24, the field plate insulation film (first insulation film) 20 is recessed at a portion thereof indicated by black arrows in FIG. 13. Accordingly, when thermal oxidation is performed, as a result of depletion of the oxidizing gas in the smaller volume region adjacent the projecting conductor 22, the film thickness of the gate insulation film 24 is decreased in the region at the lower end of the gate electrode 26 indicated by the dotted line circle in FIG. 14.

Even when the gate insulation film 24 is formed by a vapor phase epitaxial growth method such as CVD, the concentration of the source gas becomes lessened due to the recessed shape of the bottom of the opening. Accordingly, even when the gate insulation film. 24 is formed by a vapor phase epitaxial growth method, there is a possibility that a drawback that the film thickness of the gate insulation film 24 is decreased at the base of the opening.

According to the method of manufacturing a semiconductor device of the first embodiment, unlike the comparison embodiment, the gate insulation film 24 is formed after the first conductive material 22 is etched such that the upper end of the first conductive material 22 is located below the upper end of the field insulation film 20, i.e., it is recessed therein. Accordingly, contact area between e the gate electrode 26 and the field plate electrode 22 face each other is decreased.

According to this embodiment, it is possible to reduce the capacitance between the gate electrode 26 and the field plate electrode 22 by approximately 30% compared to the comparison embodiment.

Further, unlike the comparison embodiment, according to the first embodiment, the shape of the field plate insulation film (first insulation film) 20 is not recessed immediately before the formation of the gate insulation film 24. Accordingly, it is possible to suppress the decrease of the film thickness of the gate insulation film 24 which may be caused by reduction in the supply of the oxidation gas or a source gas in a region indicated by a dotted line circle in FIG. 8.

In the comparison embodiment, the film thickness of the gate insulation film 24 is decreased by approximately 30% in the region at the lower end of the gate electrode 26 indicated by a dotted line circle in FIG. 12. To the contrary, according to this embodiment, the decrease in the film thickness of the gate insulation film 24 is limited to a value within 10%.

As described above, according to the method of manufacturing a semiconductor device of this embodiment, it is possible to decrease the capacitance between the field plate electrode and the gate electrode and hence, a semiconductor device having high performance which exhibits a fast switching characteristic and the low power consumption can be realized. Further, it is possible to suppress the decrease of the film thickness of the gate insulation film and hence, a highly reliable semiconductor device can be realized.

### Second Embodiment

A method of manufacturing a semiconductor device of this embodiment is substantially equal to the method of manufacturing a semiconductor device of the first embodiment except for that re-etching of a first conductive material is performed by isotropic etching. Accordingly, the explanation of the features in common with the features of the first embodiment is omitted.

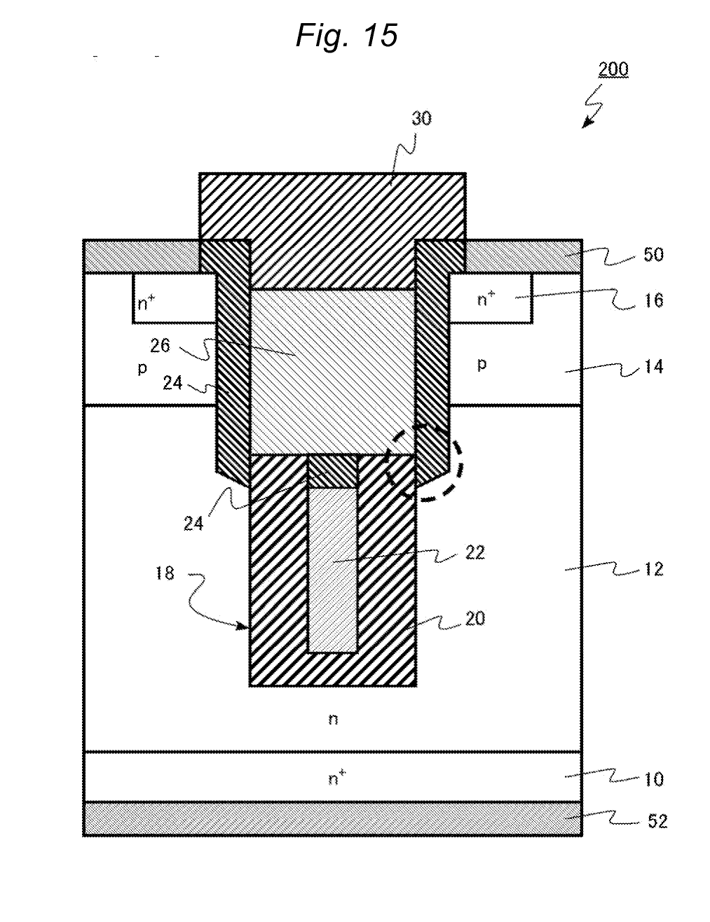

FIG. 15 is a schematic cross-sectional view of the semiconductor device manufactured by the method of manufacturing a semiconductor device according to this embodiment. A semiconductor device 200 of this embodiment is also a vertical MOSFET where a gate electrode is arranged in a trench. The semiconductor device 200 of this embodiment is substantially the same as the MOSFET 100 of the first embodiment except for that the gate insulation film of the semiconductor device 200 has a shape different from the shape of the gate insulation film of the semiconductor device 100 in the first embodiment.

As shown in FIG. 15, in the MOSFET 200 of this embodiment, a film thickness of a gate insulation film 24 in a region at a lower end of a gate electrode 26 indicated by a dotted line circle in FIG. 5 is made larger than a film thickness of the gate insulation film 24 in the region at the lower end of the gate electrode 26 in the first embodiment.

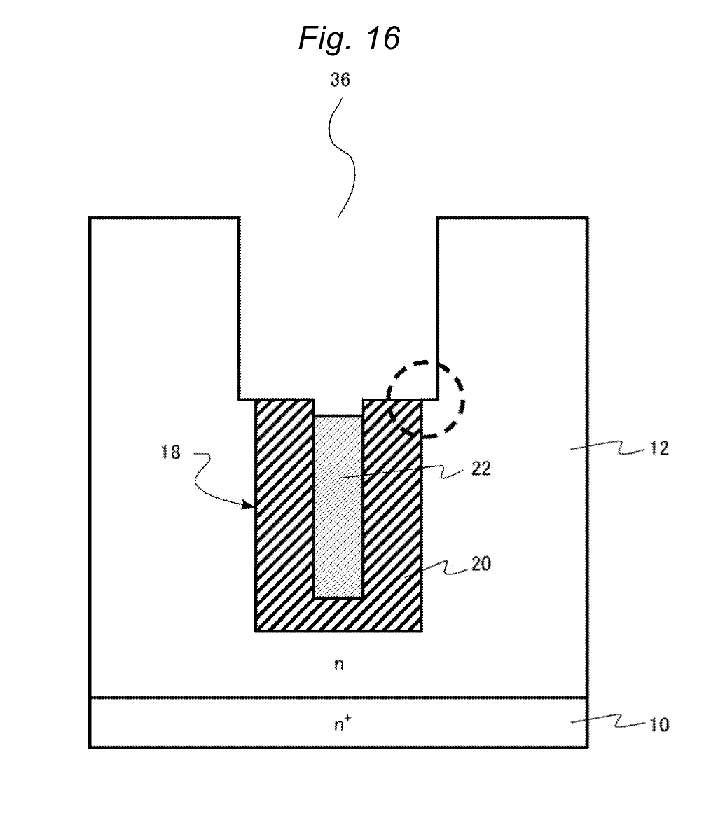

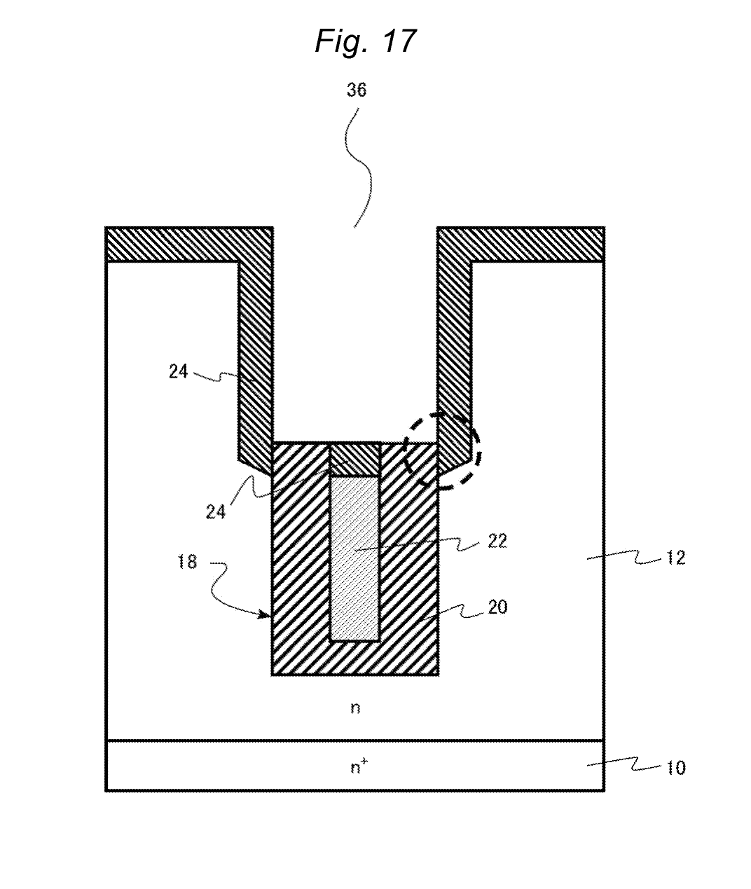

FIG. 16 and FIG. 17 are schematic cross-sectional views showing a method of manufacturing a semiconductor device of this embodiment. In the method of manufacturing a semiconductor device 200 of this embodiment, the steps up to a step where the field plate insulation film (first insulation film) 20 is etched to the condition as shown in FIG. 6 in the first embodiment are substantially the same as the steps of the first embodiment.

In this embodiment, re-etching of a first conductive material 22 is performed by isotropic etching (see FIG. 16). The isotropic etching is CDE (chemical dry etching), for example.

By etching the first conductive material 22 using the isotropic etching, the n-type semiconductor layer 12 which is exposed on an upper portion of a trench 18 is etched in all directions, including into the sidewalls of the trench 18 also etched sideward. Accordingly, the trench 18 expands to the sides thereof in an upper end portion (indicated by a dotted line circle in FIG. 16) of a field plate insulation film (first insulation film) 20 and hence, an exposed area of the n-type semiconductor layer 12 at the base of the trench is increased.

Accordingly, when the gate insulation film 24 is formed by thermal oxidation, an amount of oxidation gas supplied to the n-type semiconductor layer 12 is increased in an upper end portion (indicated by the dotted line circle in FIG. 16) of the field plate insulation film (first insulation film) 20 and hence, a film thickness of the gate insulation film 24 in the region is increased.

In this embodiment, the film thickness of the gate insulation film 24 in the region at the lower end of the gate electrode 26 indicated by a dotted line circle in FIG. 15 can be made substantially equal to the film thicknesses of the gate insulation film 24 in other regions.

According to the method of manufacturing a semiconductor device of this embodiment, the decrease of the film thickness of the gate insulation film can be further suppressed and hence, a semiconductor device having higher degree of reliability can be realized.

To perform sideward etching of the n-type semiconductor layer 12, it is desirable that the n-type semiconductor layer 12 and the first conductive material 22 are made of the same material. For example, it is desirable that both the n-type semiconductor layer 12 and the first conductive material 22 are made of silicon.

In the above-mentioned embodiments, the explanation has been made by taking the case where the first conductive type is n-type and the second conductive type is p-type as an example heretofore. However, the semiconductor device may be constituted such that the first conductive type is p-type and the second conductive type is n-type.

In the above-mentioned embodiments, the explanation has been made by taking the case where silicon is used as the semiconductor material as an example. However, other semiconductor materials such as silicon carbide (SiC), gallium nitride (GaN) may be used in the exemplified embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor layer of a first conductive type;
a first trench extending inwardly of the semiconductor layer, the first trench forming a first opening therein and a base and sidewalls;
a second trench extending inwardly of the semiconductor layer, the second trench having sidewalls, the second trench forming a second opening therein, having a diameter lager than a diameter of the first opening, and positioned above the first trench;
a first insulating film overlying an inner surface of the first trench; and
a second insulating film overlying an inner surface of the second trench.

2. The semiconductor device of claim 1, further comprising a first electrode located within the first trench, and spaced from the sidewalls of the first trench by the first insulating film.

3. The semiconductor of claim 2, wherein the first electrode extends within the first insulating film and terminates within the first portion of the first trench.

4. The semiconductor of claim 4, further comprising a third insulating film formed over the first electrode.

5. The semiconductor of claim 4, wherein the third insulating film formed over the first electrode extends inwardly of a recess in the first insulating film.

6. The semiconductor device of claim 1, wherein the sidewall of the second trench includes a tapered portion extending between the first trench and the second trench.

7. The semiconductor of claim 6, further comprising a second electrode located within the second trench.

8. The semiconductor of claim 6, wherein the second insulating film terminates inwardly of the second trench along the tapered portion thereof.

9. The semiconductor of claim 8, further comprising a third electrode location outward of, and to either side of, the second trench.

10. The semiconductor of claim 9, wherein the third electrode comprises a source electrode, the second electrode comprises a gate electrode, and the first electrode comprises a field plate electrode.

11. The semiconductor of claim 1, wherein the second insulating layer overlies a portion of the first insulating layer.

12. A method of manufacturing a semiconductor device comprising:
forming a trench on a semiconductor layer of a first conductive type;
forming a first insulation film covering an inner surface of the trench;
forming a first conductive material on the first insulation film such that the first conductive material is embedded in the trench;
etching the first conductive material such that an upper end portion of the first conductive material is positioned in the trench;
etching the first insulation film such that the semiconductor layer is exposed on an inner surface of an upper portion of the trench and the upper end portion of the first conductive material is positioned above an upper end portion of the first insulation film;
re-etching the first conductive material such that the upper end portion of the first insulation film is positioned above the upper end portion of the first conductive material after etching the first insulation film;
forming a second insulation film covering the semiconductor layer exposed on the inner surface of the upper portion of the trench and the first conductive material; and
forming a second conductive material on the second insulation film such that the second conductive material is embedded in the trench.

13. The method of manufacturing a semiconductor device according to claim 12, wherein the second insulation film is formed by thermal oxidation of the material of the trench.

14. The method of manufacturing a semiconductor device according to claim 12, wherein re-etching of the first conductive material is performed by isotropic etching.

15. The method of manufacturing a semiconductor device according to claim 12, wherein re-etching of the first conductive material is performed by anisotropic etching.

16. The method of manufacturing a semiconductor device according to claim 12, further comprising:
etching the second conductive material such that an upper end portion of the second conductive material is positioned in the trench after forming the second conductive material in the trench;
forming a first semiconductor region of a second conductive type on the semiconductor layer by ion implantation of dopant of a second conductive type; and
forming a second semiconductor region of a first conductive type in the first semiconductor region by ion implantation of dopant of first conductive type.

17. The method of manufacturing a semiconductor device according to claim 12, wherein the second insulation film extends below the upper end of the first insulation film

18. A semiconductor device, comprising:
a trench extending inwardly of a semiconductor material, and terminating inwardly thereof, the trench having abase and sidewalls, a first portion of the trench extending from the base and a second portion of the trench, wider than the first portion thereof, extending from the second portion;
a field plate electrode embedded in the trench;
a first insulating material surrounding the field plate electrode;
a second insulating material extending along the sidewalls of the trench in the second portion, and between a portion of the first insulating material and the sidewall of the trench; and
a gate electrode located in the trench and spaced from the sidewalls thereof by the second insulating material and from the field plate electrode by the first insulating material.

19. The semiconductor device of claim 18, wherein the second insulating film is silicon oxide.
